(19) United States
(12) Patent Application Publication
(10) Pub. No.: US 2007/0228355 A1
(43) Pub. Date: Oct. 4, 2007

(54) TERAHERTZ WAVE RADIATING DEVICE

(75) Inventor: Brahm Pal SINGH, Osaka (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 11/563,916

(22) Filed: Nov. 28, 2006

(30) Foreign Application Priority Data
Dec. 6, 2005 (JP) 2005-352563

(51) Int. Cl. H01L 29/06

(52) U.S. Cl. 257/10; 977/950; 977/742

(57) ABSTRACT

Provided is a terahertz (THz) wave radiating device that radiates electromagnetic wave in a THz range, the device including: an anode electrode layer; a cathode electrode layer which forms a pair with the anode electrode layer; an electrical insulating layer (i) which is positioned between the anode electrode layer and the cathode electrode layer, and (ii) in which an aperture is formed and a vacuum is produced, the aperture passing through the electrical insulating layer in a direction in which the electrical insulating layer was laminated; and a photoelectron emission layer (i) which is positioned between the electrical insulating layer and the cathode electrode layer, (ii) which touches the electrical insulating layer, and (iii) which emits photoelectrons to the aperture.

### BACKGROUND OF THE INVENTION

(1) Field of the Invention

The present invention relates to a terahertz (THz) wave radiating device that radiates electromagnetic wave in the terahertz range.

(2) Description of the Related Art

In recent years, electromagnetic wave in the terahertz frequency range (hereinafter referred to as “THz wave”) has attracted considerable attention. Electromagnetic wave radiations in the range from 0.1 to 10 THz have straight beam traveling characteristics (i.e., focusing ability) and transparency through various objects such as ceramic, plastic, paper, etc. Owing to these characteristics, THz wave is applied in various fields such as spectroscopy, biomedicine, security and imaging. Against this backdrop, with the view to finding further new applications as well as in consideration of increased security reasons and drugs trafficking problems, development of compact and portable high power THz wave radiation sources is actively underway (for example, see Japanese Laid-Open Patent Application No. 2004-172177).

FIG. 1 is an oblique view showing an example structure of a conventional THz wave radiating device. As shown in FIG. 1, a THz wave radiating device 10 has a structure in which a thin low temperature grown gallium arsenide (hereinafter referred to as “LT-GaAs”) layer 12 that is a few micrometer-thick is grown on an insulating GaAs wafer 11. Furthermore, an electrode 13 and an electrode 14 are formed on the LT-GaAs layer 12. The shapes of the electrode 13 and electrode 14 are each convex in the direction of lamination, and a salient portion of the electrode 13 and a salient portion of the electrode 14 are placed opposite to each other.

A high DC voltage is applied to the electrode 13 and the electrode 14 from a DC bias supply 15. Then, high peak power subpicosecond pulsed laser is irradiated in the gap (2 to 1000 μm) between the electrode 13 and the electrode 14, which is the space between the salient portion of the electrode 13 and the salient portion of the electrode 14, to generate an electrostatic discharge, and THz wave is generated as a result. In this way, a compact THz wave radiating device is realized.

However, the conventional THz wave radiating device has the following problems: the bandwidth of THz wave to be generated is limited since the gap between the electrodes is uniform; the THz wave radiation power is limited since the break down voltage of the GaAs device is low; and current leakage occurs if voltage is forcedly increased.

### SUMMARY OF THE INVENTION

In view of the above problems, it is an object of the present invention to provide a THz wave radiating device and a fabrication method thereof, the THz wave radiating device being current leak proof to stand for a high voltage and achieving an increased efficiency of THz wave radiation. Another object of the present invention is to provide a THz wave radiating device and a fabrication method thereof, the THz wave radiating device being capable of radiating broadband THz wave, being mass-producible and highly reliable, and being capable of low-cost fabrication.

In order to achieve the above objects, the THz wave radiating device according to the present invention is (a) a THz wave radiating device that radiates electromagnetic wave in a THz range, the device including: (a1) a first electrode layer; (a2) a second electrode layer which forms a pair with the first electrode layer; (a3) an electrical insulating layer (i) which is positioned between the first electrode layer and the second electrode layer, and (ii) in which an aperture is formed and a vacuum is produced, the aperture passing through the electrical insulating layer in a direction in which the electrical insulating layer was laminated; and (a4) a photoelectron emission layer (i) which is positioned between the electrical insulating layer and the second electrode layer, (ii) which touches the electrical insulating layer, and (iii) which emits photoelectrons to the aperture.

With the above structure, current leakage is unlikely to occur even when a high voltage is applied to the first electrode layer (anode electrode layer) and the second electrode layer (cathode electrode layer). This is attributable to having the electrical insulating layer between the first electrode layer (anode electrode layer) and the second electrode layer (cathode electrode layer). As a result, it is possible to apply a high voltage to the THz wave radiating device and thus to improve the efficiency of THz wave radiation.

Furthermore, (b) the THz wave radiating device may include: (b1) a first wafer in which the first electrode layer is formed; and (b2) a second wafer in which the second electrode layer and the photoelectron emission layer are formed, (b3) wherein the electrical insulating layer is sandwiched between the first wafer and the second wafer in such a manner that a surface of the second wafer on which the photoelectron emission layer is formed is opposite to a surface of the first wafer on which the first electrode layer is formed.

With the above structure, it is possible to fabricate the THz wave radiating device through semiconductor fabrication processes, and thus to provide a THz wave radiating device which is mass-producible and highly reliable, and which is capable of low-cost fabrication.

Furthermore, (c) a V groove may be formed on a surface of the second wafer opposite to a surface on which the second electrode layer is formed, and the photoelectron emission layer is formed on an outer surface of the V groove.

With the above structure, it is possible to control the frequency of THz wave to be radiated from the THz wave radiating device depending on the distance from the first electrode layer (anode electrode layer) formed in the first wafer (anode wafer) to the photoelectron emission layer formed on the V groove. In other words, the frequency of THz wave is represented by a function of the gap between the first electrode layer (anode electrode layer) and the photoelectron emission layer. Thus, the THz wave radiating device, in which the gap between the first electrode layer (anode electrode layer) and the photoelectron emission layer is variable depending on portion, is capable of radiating THz wave including various frequency components and thus radiating broadband THz wave.

More specifically, THz wave radiated from the THz wave radiating device can be precisely controlled by the range from few μm to few mm, depending on the depth of the V groove and the thickness of the electrical insulating layer formed in the second wafer (cathode wafer). The depth of the V groove can be controlled by performing semiconductor micro-processes such as photolithography and etching. This allows precise control of the positions of the first electrode layer (anode electrode layer) and the second electrode layer (cathode electrode layer) as well as the gap between them, and thus to allow the THz wave radiating device to radiate THz wave with a desired spectral bandwidth.

Alternatively, (d) two V grooves may be formed on the surface of the first wafer on which the first electrode layer is formed, and the first electrode layer is formed over the two V grooves.

With the above structure, the electrical field is more focused on the first electrode layer (anode electrode layer) than on the electrical insulating layer, since the tip of the first electrode layer (anode electrode layer) is positioned immediately above the V groove. As a result, even if a high voltage is applied, current leakage is unlikely to occur in the electrical insulating layer, and thus it is possible to achieve high power THz wave radiations.

Alternatively, (e) the photoelectron emission layer may be λ/4n in thickness, where λ is a wavelength of incident light irradiated on the photoelectron emission layer, and n is a refractive index of the photoelectron emission layer.

With the above structure, the reflection of incident light (femtosecond pulsed laser) is suppressed, and thus the loss in the amount of laser light to be irradiated decreases and the operating efficiency is improved.

Alternatively, (f) an outer surface of the photoelectron emission layer may have periodic irregularities.

With the above structure, periodic variations are produced in the refractive index of the photoelectron emission layer and the refractive index of the outer environment (e.g., vacuum). Such a periodic variation in a refractive index is known as photonic crystal. In other words, an appropriately designed photonic crystal can absorb maximum incident light (femtosecond pulsed laser) with least reflection. Furthermore, the periodic irregularities on the outer surface of the photoelectron emission layer allow its area to be virtually doubled compared with the actual area. As a result, it is possible to best convert incident light (femtosecond pulsed laser) into THz wave.

Alternatively, (g) the photoelectron emission layer may be made of one of the following carbon nanostructures: carbon nanotube, carbon nanowall, and carbon nanofiber.

Moreover, (h) an effective length of the carbon nanotube may range from 50 nm to 50 μm.

With the above structure, since the carbon nanotube has very fine tip, it can provide a point like THz wave radiation source to enhance the imaging resolution. Thus, the use of carbon nanotube as the photoelectron emission layer allows the THz wave radiating device to be fabricated at low cost, allowing its practical use. Moreover, the THz wave radiating device will provide an efficient field emission and photoelectron emission to result in high power THz wave radiations, and thus it contributes to new applications of THz wave.

Alternatively, (i) one of the first electrode layer and the second electrode layer may be made of a material having transparency to incident light.

Furthermore, (j) the material may include Indium Tin Oxide (ITO).

With the above structure, the use of ITO for the first electrode layer (anode electrode layer) makes it easier for incident light (femtosecond pulsed laser) to be irradiated over the outer surface of the photoelectron emission layer. This structure results in the reduction in the size of the THz wave radiating device as well as in an easier fabrication of the same.

Alternatively, (k) one of the first electrode layer and the second electrode layer may be in a mesh form.

Furthermore, (l) a pitch size of the mesh may range from 10 μm to 300 μm.

With the above structure, the second electrode layer (cathode electrode layer)/first electrode layer (anode electrode layer) is capable of controlling the phase of THz wave and serving as a filter.

Alternatively, (m) a groove may be formed on a surface of the second wafer opposite to a surface on which the second electrode layer is formed, and a chip may be assembled with the groove, the chip including the photoelectron emission layer thereon.

Furthermore, (n) a V groove may be formed on a surface of the chip opposite to a surface which touches the groove formed in the second wafer, and the photoelectron emission layer may be formed on an outer surface of the V groove.

With the above structure, by using SiC only for the chip and using a Si substrate for the cathode wafer except for the chip portion, it is possible to fabricate the THz wave radiating device at low cost, compared with the case where SiC is used for the second wafer (cathode wafer).

Alternatively, a notch may be formed in the THz wave radiating device in a direction in which the electromagnetic wave is irradiated.

With the above structure, it is possible for the THz wave radiating device to radiate directional THz wave.

It should be noted that the present invention can be embodied not only as a THz wave radiating device, but also as: a method for fabricating a THz wave radiating device; a THz wave radiating system in which the THz wave radiating device is embedded; a method for driving the THz wave radiating device; and the like.

As described above, the present invention will enable the mass production of THz wave radiating devices with photoelectron emission layer at low cost.

Further Information about Technical Background to this Application

The disclosure of Japanese Patent Application No. 2005-352563 filed on Dec. 6, 2005 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is an oblique view showing an example structure of the conventional THz wave radiating device;

FIG. 2 is a cross-sectional view showing the structure of a THz wave radiating device according to an embodiment of the present invention;

FIG. 3A is a block diagram showing the structure of a THz wave radiating system in which the THz wave radiating device of an embodiment of the present invention is embedded;

FIG. 3B is a waveform diagram showing laser beam output from a laser device to the THz wave radiating device of an embodiment the present invention as well as a bias voltage supplied from a bias supply;

FIG. 4 is a diagram showing the structure of the THz wave radiating system in which the THz wave radiating device of an embodiment of the present invention is embedded;

FIG. 5 is a flowchart showing processes of fabricating the THz wave radiating device of an embodiment of the present invention;

FIG. 6 is a flowchart showing an example variant embodiment of the processes of fabricating the photoelectron emission layer included in the THz wave radiating device of the present invention;

FIG. 7 is a cross-sectional view showing a first variant embodiment of the THz wave radiating device of the present invention;

FIG. 8 is a flowchart showing the processes of fabricating the THz wave radiating device of the first variant embodiment;

FIG. 9 is a cross-sectional view showing a second variant embodiment of the THz wave radiating device of the present invention;

FIG. 10 is a cross-sectional view showing a third variant embodiment of the THz wave radiating device of the present invention;

FIG. 11 is a cross-sectional view showing a fourth variant embodiment of the THz wave radiating device of the present invention;

FIG. 12 is a cross-sectional view showing a fifth variant embodiment of the THz wave radiating device of the present invention;

FIG. 13A is an enlarged oblique view showing a photoelectron emission layer of the THz wave radiating device of the fifth variant embodiment;

FIG. 13B is an oblique view showing a variant embodiment of the photoelectron emission layer of the THz wave radiating device of the fifth variant embodiment;

FIG. 14 is a cross-sectional view showing a sixth variant embodiment of the THz wave radiating device of the present invention;

FIG. 15A is an enlarged oblique view showing a photoelectron emission layer of a THz wave radiating device of the sixth variant embodiment;

FIG. 15B is an oblique view showing a variant embodiment the photoelectron emission layer of the THz wave radiating device of the sixth variant embodiment;

FIG. 16 is a cross-sectional view showing a seventh variant embodiment of the THz wave radiating device of the present invention;

FIG. 17 is a cross-sectional view showing an eighth variant embodiment of the THz wave radiating device of the present invention;

FIG. 18A is a top view showing a ninth variant embodiment of the THz wave radiating device of the present invention;

FIG. 18B is a cross-sectional view showing the THz wave radiating device of the ninth variant embodiment when it is cut along the line A-A and seen in the direction indicated by the arrows;

FIG. 19A is a top view showing a tenth variant embodiment of the THz wave radiating device of the present invention;

FIG. 19B is a cross-sectional view showing the THz wave radiating device of the tenth variant embodiment when it is cut along the line B-B and seen in the direction indicated by the arrows; and

FIG. 20 is an oblique view showing a variant embodiment of any of the cathode electrode layer and the anode electrode layer in the THz wave radiating device of the present invention.

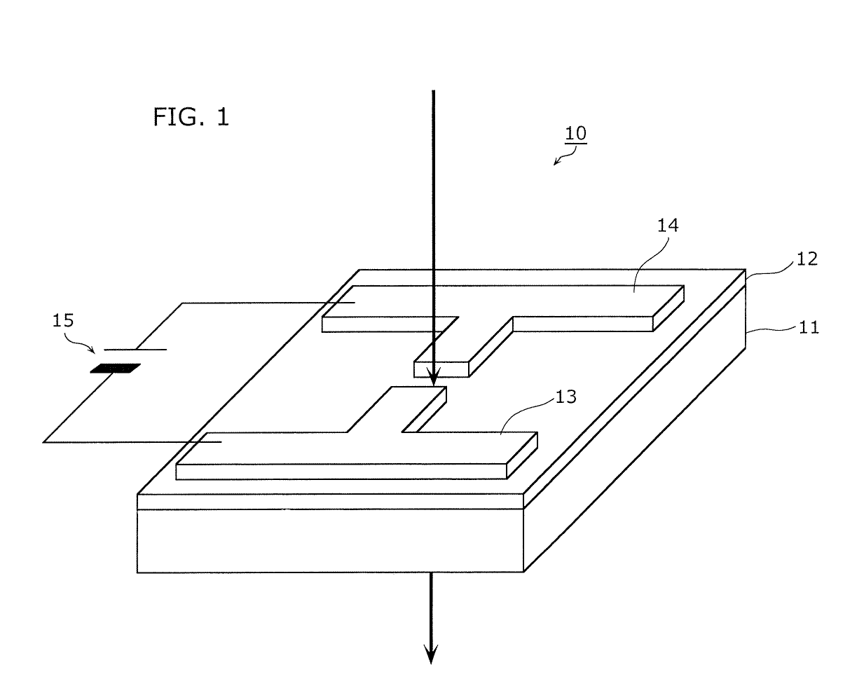

### DESCRIPTION OF THE PREFERRED EMBODIMENT

A preferred embodiment of the present invention will hereinafter be described with reference to the attached drawings.

The THz wave radiating device according to the present invention is (a) a THz wave radiating device that radiates electromagnetic wave in a THz range, the device including: (a1) a first electrode layer; (a2) a second electrode layer which forms a pair with the first electrode layer; (a3) an electrical insulating layer (i) which is positioned between the first electrode layer and the second electrode layer, and (ii) in which an aperture is formed and a vacuum is produced, the aperture passing through the electrical insulating layer in a direction in which the electrical insulating layer was laminated; and (a4) a photoelectron emission layer (i) which is positioned between the electrical insulating layer and the second electrode layer, (ii) which touches the electrical insulating layer, and (iii) which emits photoelectrons to the aperture.

Furthermore, (b) the THz wave radiating device includes: (b1) a first wafer in which the first electrode layer is formed; and (b2) a second wafer in which the second electrode layer and the photoelectron emission layer are formed, (b3) wherein the electrical insulating layer is sandwiched between the first wafer and the second wafer in such a manner that a surface of the second wafer on which the photoelectron emission layer is formed is opposite to a surface of the first wafer on which the first electrode layer is formed.

The THz wave radiating device of the present embodiment will be described based on the above-described features.

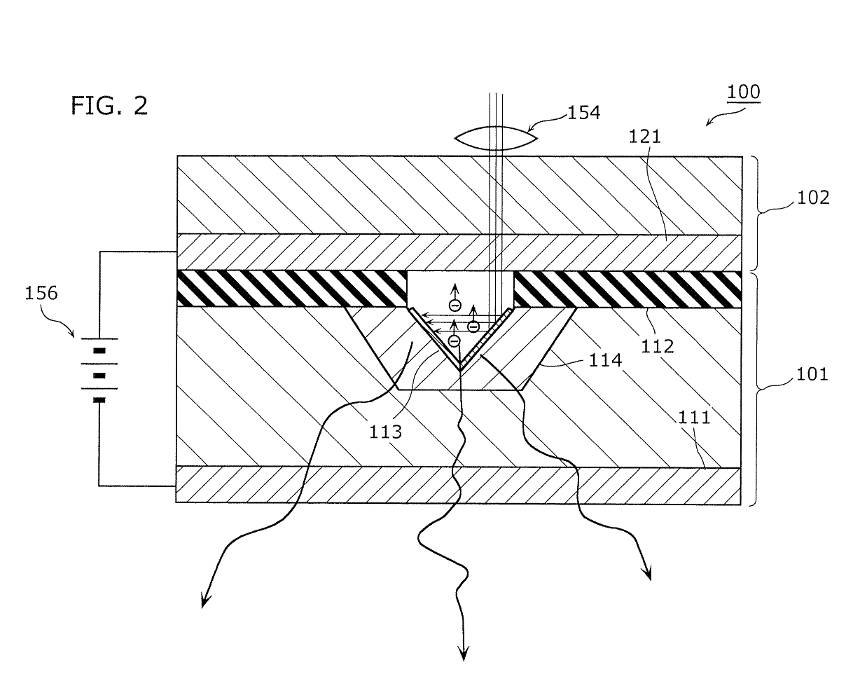

FIG. 2 is a diagram showing the structure of a THz wave radiating device according to the present embodiment. As shown in FIG. 2, the THz wave radiating device 100 includes a cathode wafer 101 and an anode wafer 102. The cathode wafer 101 and the anode wafer 102 are wafer-bonded. The cathode wafer 101 is a wafer in which a cathode electrode layer 111 is formed. The cathode electrode layer 111 is an electrode layer formed by depositing the nickel layer of about 200 nm in thickness onto the cathode wafer 101 and annealing it at 950 to 1000° C. for 2 minutes or at 1100 to 1150° C. for 1 minute to make Ohmic contact with the contact resistance below 0.0001 Ohm. This cathode electrode layer 111 is connected to a bias supply 156.

The anode electrode 102 is a wafer in which an anode electrode layer 121 is formed. The anode electrode layer 121 is an electrode layer formed by depositing, onto the anode wafer 102, a material such as Indium Tin Oxide (ITO) having transparency through ultra-short pulse light such as femtosecond laser. This anode electrode layer 121 is connected to the bias supply 156.

The use of ITO for the anode electrode layer 121 makes it easier for laser light to be irradiated over the outer surface of the photoelectron emission layer 113. This structure results in the reduction in the size of the THz wave radiating device 100 and makes it easier to fabricate the THz wave radiating device 100.

Furthermore, in the cathode wafer 101, an electrical insulating layer 112 is formed on the surface opposite to the surface on which the cathode electrode layer 111 is formed, and an aperture is formed that passes through the electrical insulating layer 112 in the direction in which the electrical insulating layer 112 was laminated. The electrical insulating layer 112 is formed on the cathode wafer 101 using a material such as silicon dioxide (SiO₂) and silicon nitride (Si₃N₄). Furthermore, a V groove is formed in the cathode wafer 101 in accordance with the position of the aperture, and a photoelectron emission layer 113 is formed on the outer surface of this V groove. Here, as an example, the photoelectron emission layer 113 is assumed to be a layer with a carbon nanostructure formed on the outer surface of the V groove formed in the chip 114 made of silicon carbide (SiC). The carbon nanostructure includes carbon nanotube, carbon nanowall, and carbon nanofiber. Of these, the carbon nanotube layer can be grown on the SiC wafer by means of Chemical Vapor Deposition (CVD). The carbon nanotube layer can also be grown by annealing the SiC wafer for about an hours at high temperature in the range from 1200° C. to 2000° C. in a partially oxygen containing medium in the chamber. For example, a flat surface SiC wafer with a small size, say 10 mm×10 mm, is annealed at 1200° C. to 2000° C. for an hour to grow over 50 nm-thick carbon nanotube layer containing a variety of multiwall carbon nanotubes with their top end generally closed.

Note that, when λ denotes the wavelength of the laser and n denotes the refractive index of the photoelectron emission layer 113, the thickness of the photoelectron emission layer 113 is represented as λ/4n. This is because an optical film with the thickness of λ/4n serves in general as antireflection coating. As a result, laser light reflection is suppressed, and thus the loss in the amount of laser light to be irradiated decreases and the operating efficiency is improved.

However, in order for the electric field to be focused on the carbon nanotube, the length-diameter aspect ratio of the carbon nanotube is preferably 10 to 1, or greater. However, when the aspect ratio exceeds 100-times greater, the carbon nanotube is likely to fall.

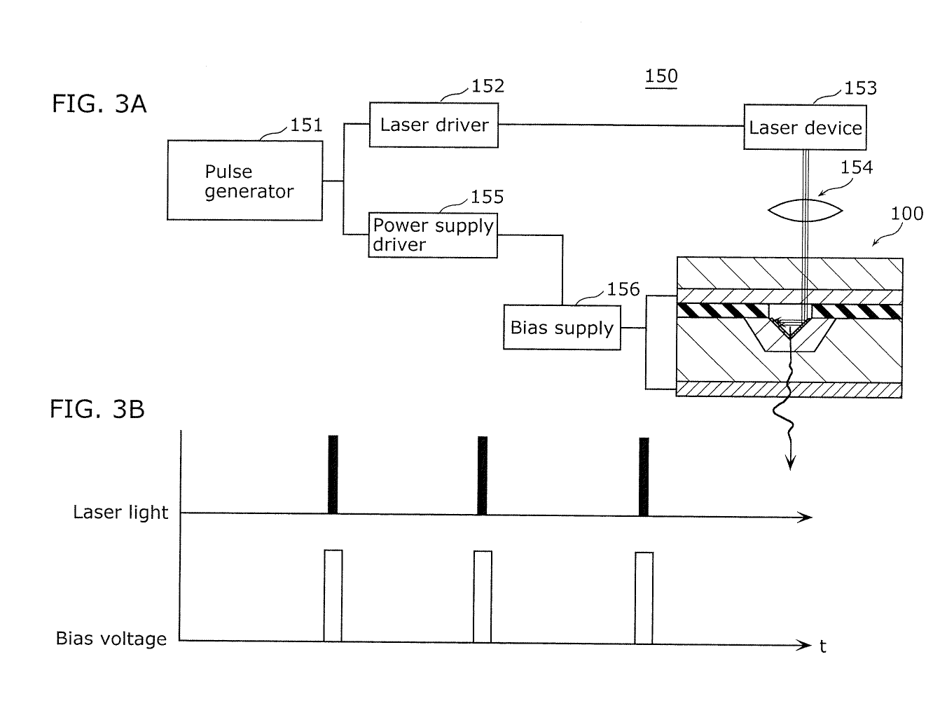

FIG. 3A is a diagram showing the structure of a THz wave radiating system in which the THz wave radiating device 100 of the present embodiment is embedded. As shown in FIG. 3A, a THz wave radiating system 150 includes a pulse generator 151, a laser driver 152, a laser device 153, a lens 154, a power supply driver 155, a bias supply 156, and the THz wave radiating device 100.

The pulse generator 151 generates pulses to be output to the laser driver 152 and the power supply driver 155. The pulse generator 151 outputs the generated pulses to the laser driver 152 and the power supply driver 155.

The laser driver 152 drives the laser device 153 according to the pulse output from the pulse generator 151.

The laser device 153 outputs a high peak power femtosecond pulsed laser upon being driven by the laser driver 152. As an example, a femtosecond pulsed laser with the wavelength of 250 nm to 1600 nm is used, which is based on the work function of a carbon nanostructure such as carbon nanotube.

The femtosecond pulsed laser output from the laser device 153 is focused by the lens 154.

The power supply driver 155 drives the bias supply 156 according to the pulse output from the pulse generator 151.

The bias supply 156 supplies a high DC bias voltage to the cathode electrode layer 111 and the anode electrode layer 121 upon being driven by the power supply driver 155.

FIG. 3B is a waveform diagram showing laser beam output from the laser device 153 to the THz wave radiating device 100 of the present embodiment as well as a bias voltage supplied from the bias supply 156. As shown in FIG. 3B, the pulse generator 151 may output pulses to the laser driver 152 and the power supply driver 155 in a synchronized manner, so that the supply of a DC bias voltage and the output of laser are synchronized with each other. With this structure, it is possible to achieve an improved signal-to-noise (S/N) ratio and thus an enhanced THz wave radiation efficiency. When there is no laser irradiation, electrons emitted by the electric field becomes the noise source. Therefore, by synchronizing the supply of a DC bias voltage and the output of laser, it is possible to suppress noise.

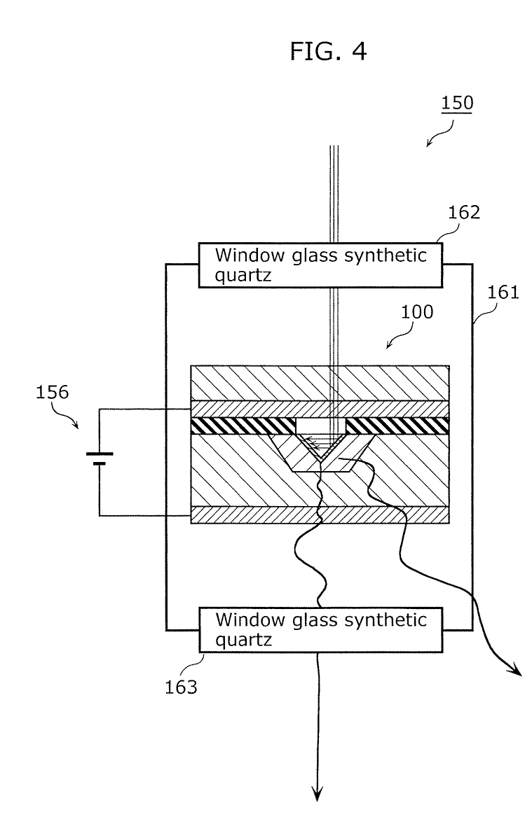

FIG. 4 is a diagram showing the structure of the THz wave radiating system 150 in which the THz wave radiating device 100 of the present embodiment is embedded. More specifically, as shown in FIG. 4, the THz wave radiating device 100 is sealed in a container 161 in which the vacuum pressure is set at 4E-6 Torr or lower. A high peak power femtosecond pulsed laser is focused with the lens 154 and is irradiated through the window glass synthetic quartz 162. Then, the laser passes through the anode wafer 102, and the laser which has passed through the anode wafer 102 is irradiated on the photoelectron emission layer 113, from which efficient photoelectrons are emitted. The emitted photoelectrons are accelerated by applying a high DC voltage to the cathode electrode layer 111 and the anode electrode layer 121 from the bias supply 156 to radiate THz wave. The THz wave generated by the THz wave radiating device 100 is irradiated through the window glass synthetic quartz 163.

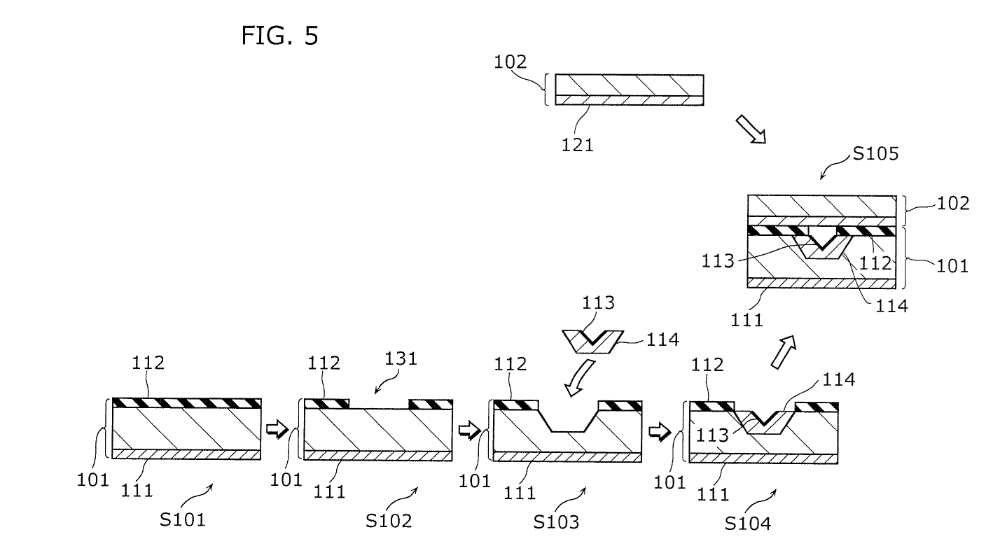

FIG. 5 is a flowchart showing the processes of fabricating the THz wave radiating device of the present embodiment. As shown in FIG. 5, the electrical insulating layer 112 is formed on the cathode wafer 101 in which the cathode electrode layer 111 is formed (S101). When this is done, the electrical insulating layer 112 is formed on the surface of the cathode wafer 101 opposite to the surface on which the cathode electrode layer 111 is formed. Furthermore, the aperture 131 is formed in the electrical insulating layer 112 by photolithography and etching. The aperture 131 passes through the electrical insulating layer 112 in the direction in which the electrical insulating layer 112 was laminated (S102). Then, a groove is formed at a portion exposed by the aperture 131 by means of anisotropic etching (S103). A fluid containing the chip 114 (SiC), in which the photoelectron emission layer 113 is formed on the V groove of the chip 114, is poured onto the surface where the groove is formed, so as to assemble the chip 114 with the groove (S104). Then, the cathode wafer 101 and the anode wafer 102 are wafer-bonded (S105). When this is done, the cathode electrode layer 111 and the anode electrode layer 121 are bonded in such a manner that the photoelectron emission layer 113 is located between these electrodes.

Then, the THz wave radiating device 100 that has been completed by wafer-bonding the cathode wafer 101 and the anode wafer 102 are sealed into the container 161 in which the vacuum pressure is set to 4E-6 Torr or lower, thereby allowing the space between the anode electrode layer 121 and the photoelectron emission layer 113 to be under vacuum.

Note that the use of fluid enables the chip 114 to be gently assembled with the groove, without damaging the outer surface of the photoelectron emission layer 113. Furthermore, since the use of fluid enables the chip 114 to be assembled in a self-aligned manner, there is no need for an assembling device with high accuracy. As a result, a high-quality THz wave radiating device 100 is realized. The method of assembling the chip using fluid is described, for example, in B. P. Singh, K. Onozawa, K. Yamanaka, T. Tojo, and D. Ueda: IEEE/LEOS OPTICAL MEMS 2004 Int. Conf. on Optical MEMS and Their Applications, Takamatsu, 2004, Japan, pp. 176-177.

Note that other than being a Si wafer, the cathode wafer 101 may also be an n-type 6H—SiC wafer, a semi-insulating 6H—SiC wafer, an n-type 4H—SiC wafer, and other poly type SiC wafers. Furthermore, the V groove may be formed directly in the cathode wafer 101, such that the photoelectron emission layer 113 is formed on the V groove. The cathode wafer 101 may be replaced by a SiC wafer with an off-angle. In this case, the off-angle is set so that the angle of the inclined surfaces of the V groove with respect to the outer surface of the cathode wafer 101 is 45 degree. Meanwhile, in the case where off-angle is not employed, the angle of the inclined surfaces of the V groove with respect to the outer surface of the cathode wafer 101 is usually 54.7 degree. Note that other than being a Si wafer, the anode wafer 102 may also be an n-type 6H—SiC wafer, a semi-insulating 6H—SiC wafer, an n-type 4H—SiC wafer, and other poly type SiC wafers.

The anode wafer 102 may also be a SiC wafer with an off-angle. As described above, the THz wave radiating device 100 of the present embodiment is capable of controlling the frequency band of THz wave it irradiates, depending on the distance from the anode electrode layer 121 formed in the anode wafer 102 to the photoelectron emission layer 113 formed on the V groove. In other words, since the frequency band of THz wave is represented by a function of the gap between the photoelectron emission layer 113 and the anode electrode layer 121, and when such gap is not uniform, the THz wave radiating device 100 is capable of radiating THz wave including a variety of frequency components and is thus capable of radiating broadband electromagnetic wave.

More specifically, the band of THz wave radiated from the THz wave radiating device 100 can be precisely controlled by the range from few μm to few mm, depending on the depth of the V groove and the thickness of the electrical insulating layer 112 formed in the cathode wafer 101. The depth of the V groove can be controlled by performing a semiconductor micro-process such as photolithography and etching. This allows precise control of the positions of the anode electrode layer 121 and the cathode electrode layer 111 as well as the gap between them, and thus to allow the THz wave radiating device 100 to radiate THz wave with a desired spectral bandwidth.

Furthermore, since the carbon nanotube has very fine tip, it can provide a point like THz wave radiation source to enhance the imaging resolution. Thus, the use of carbon nanotube as the photoelectron emission layer 113 allows the THz wave radiating device 100 to be fabricated at low cost. Moreover, the THz wave radiating device 100 will provide an efficient field emission and photoelectron emission to result in high power THz wave radiations, and thus it contributes to new applications of THz wave.

Note that when forming a carbon nanostructure (the photoelectron emission layer 113) on the V groove, SiC deposited on a carbon board by means of CVD may be used instead of a SiC wafer.

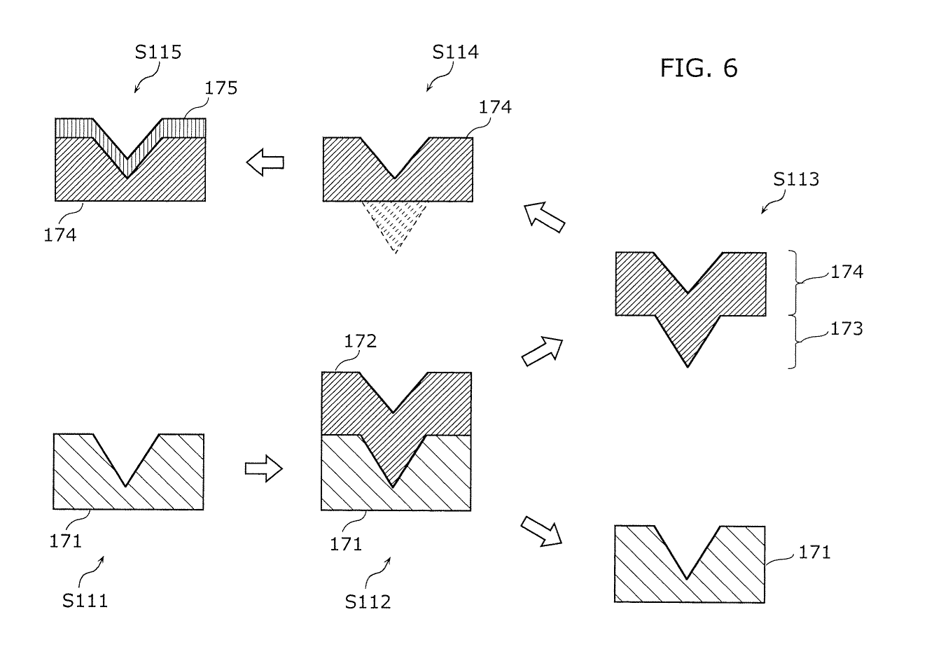

FIG. 6 is a flowchart showing an example variant embodiment of the processes of fabricating the photoelectron emission layer included in the THz wave radiating device of the present embodiment. More specifically, as shown in FIG. 6, a carbon board 171 with a V groove is used (S111). SiC is deposited by means of CVD on the surface of the carbon board 171 on which the V groove is formed (S112). After depositing the SiC to a predetermined thickness, the SiC deposit 172 deposited on the carbon board 171 is separated from the carbon board 171 (S113). After the separation, the surface of the SiC deposit 172 which faced the carbon board 171, i.e., the bottom portion 173 of the SiC deposit 172, is polished to form a smooth outer surface (S114). After the polishing, by annealing at high temperature the SiC deposit 172 on the surface opposite to the polished surface, the carbon nanostructure layer 175 (the photoelectron emission layer 113) is grown (S115).

### First Variant Embodiment

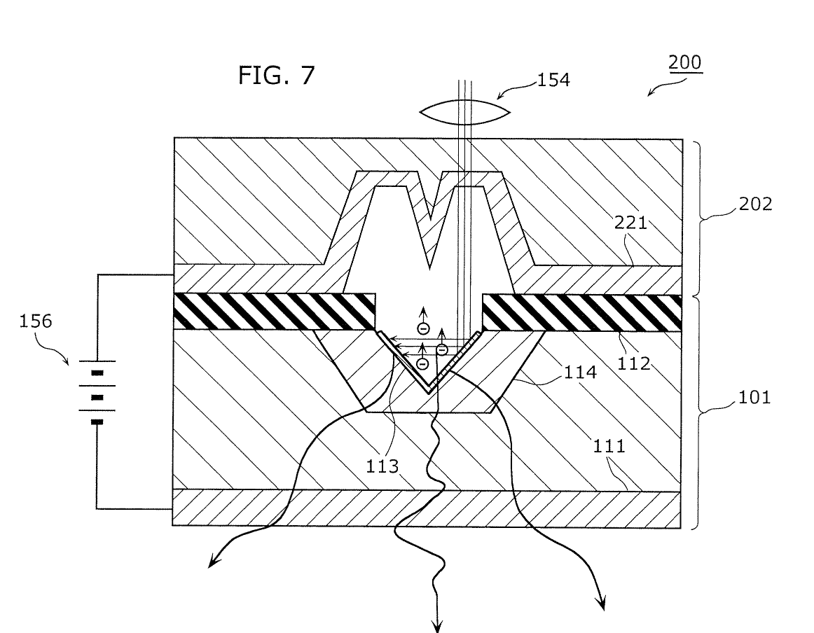

FIG. 7 is a cross-sectional view showing the first variant embodiment of the THz wave radiating device of the present embodiment. As shown in FIG. 7, a THz wave radiating device 200 may include an anode wafer 202 instead of the anode wafer 102.

The anode wafer 202 includes: two V grooves formed on the surface on which an anode electrode layer 221 is formed; and the anode electrode layer 221 formed over these two V grooves. Here, the anode electrode layer 221 may be formed so that the tip of the anode electrode layer 221 is positioned immediately above the V groove formed in the cathode wafer 101.

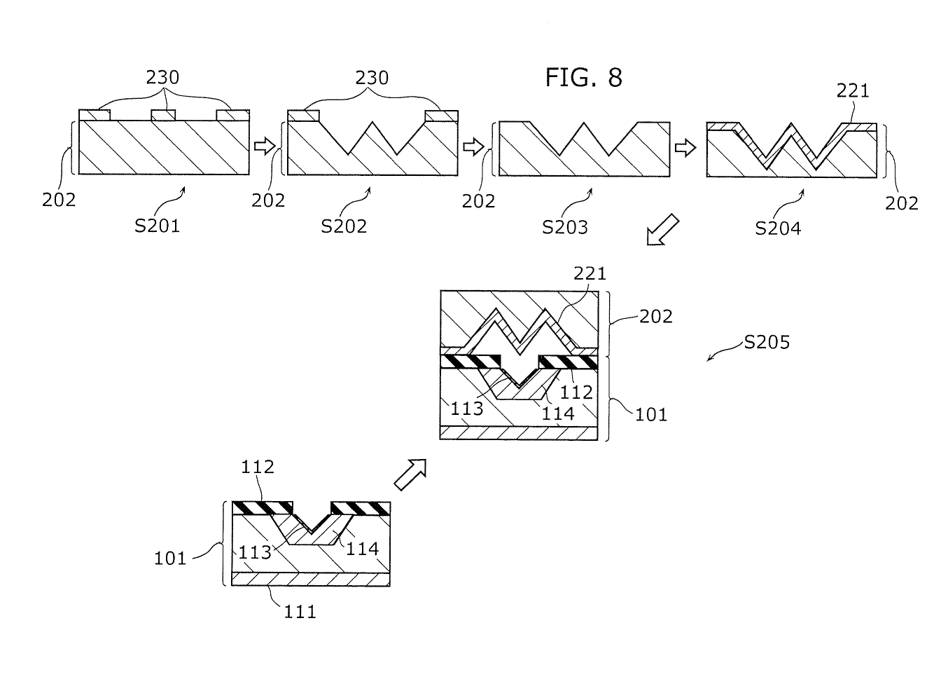

FIG. 8 is a flowchart showing the processes of fabricating the THz wave radiating device 200 of the first variant embodiment. As shown in FIG. 8, a photoresist 230 is formed on the anode wafer 202 in which the anode electrode layer 221 is formed (S201). The, two apertures are formed in the photoresist 230 by photolithography and etching. Furthermore, two V grooves are formed by means of anisotropic etching (S202), and the photoresist 230 is removed (S203). The anode electrode layer 221 is formed on the outer surface of the anode wafer 202 including the outer surface of the V grooves (S204). The cathode wafer 101 and the anode wafer 202 are wafer-boded (S205). When this is done, the cathode wafer 101 and the anode wafer 202 are wafer-boded so that the tip of the anode electrode layer 221 is positioned immediately above the V groove formed in the cathode wafer 101.

This structure enables the electrical field to be focused more on the anode electrode layer 221 than on the electrical insulating layer 112, since the tip of the anode electrode layer 221 is positioned immediately above the V groove. As a result, even if a high voltage is applied, current leakage is unlikely to occur in the electrical insulating layer, and thus it is possible to achieve high power THz wave radiations.

### Second Variant Embodiment

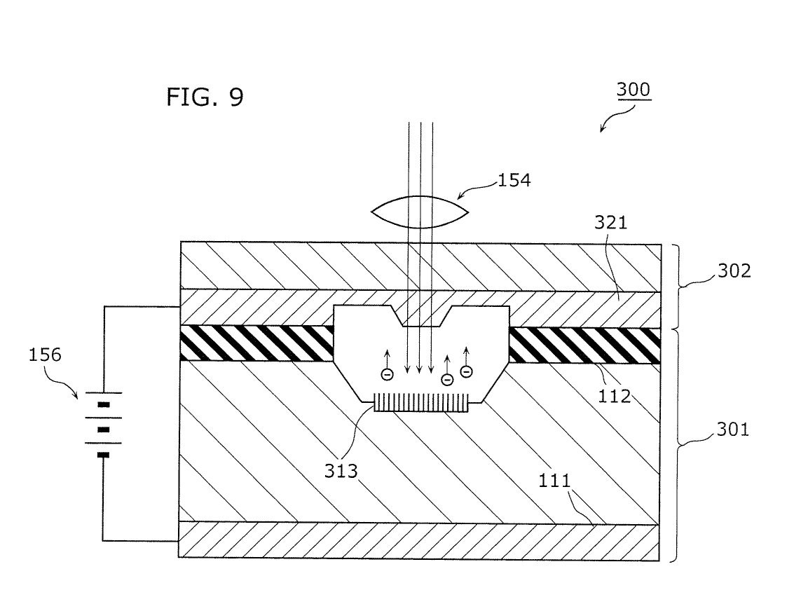

FIG. 9 is a cross-sectional view showing the second variant embodiment of the THz wave radiating device of the present embodiment. As shown in FIG. 9, a THz wave radiating device 300 may have a structure in which a groove is formed in a cathode wafer 301, and a photoelectron emission layer 313 (carbon nanotube layer) is formed at the bottom of this groove. Furthermore, the THz wave radiating device 300 may also include an anode wafer 302 in which an anode electrode layer 321 having a protruding portion is formed. Furthermore, the cathode wafer 301 and the anode wafer 302 may be bonded in such a manner that the protruding portion of the anode electrode layer 321 is positioned immediately above the photoelectron emission layer 313 (carbon nanotube layer). With the above structure, it is possible for the THz wave radiating device 300 to radiate highly efficient THz wave. Here, it is assumed that the cathode wafer 301 is formed by use of a SiC wafer.

### Third Variant Embodiment

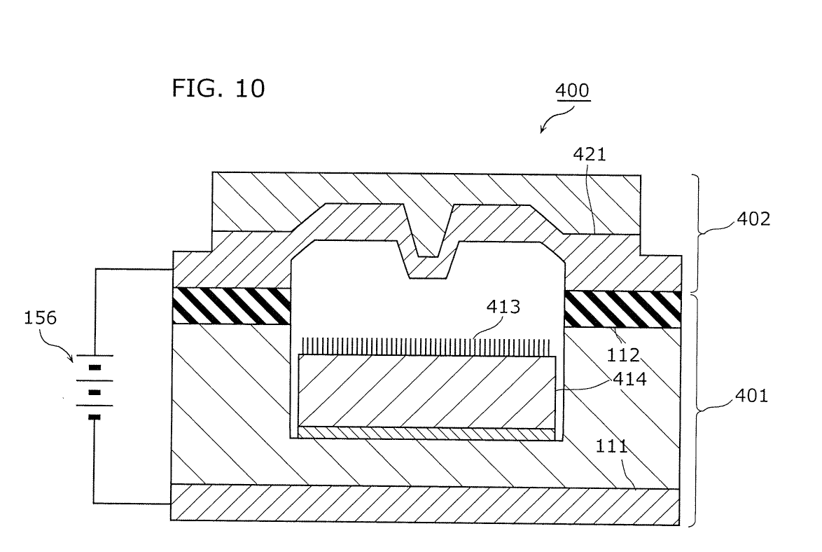

FIG. 10 is a cross-sectional view showing the third variant embodiment of the THz wave radiating device of the present embodiment. As shown in FIG. 10, a THz wave radiating device 400 may have a structure in which a groove is formed in a cathode wafer 401, and a chip 414, on which a photoelectron emission layer 413 is formed and the bottom surface of which is electroplated, is assembled in the bottom of the groove. Here, the chip 414 may be SiC, and the cathode wafer 401 may be formed by use of either a Si wafer or a SiC wafer. A fluid containing the chip 414 is poured onto the surface of the cathode wafer 401 on which the groove is formed, so as to assemble the chip 414 with the groove.

### Fourth Variant Embodiment

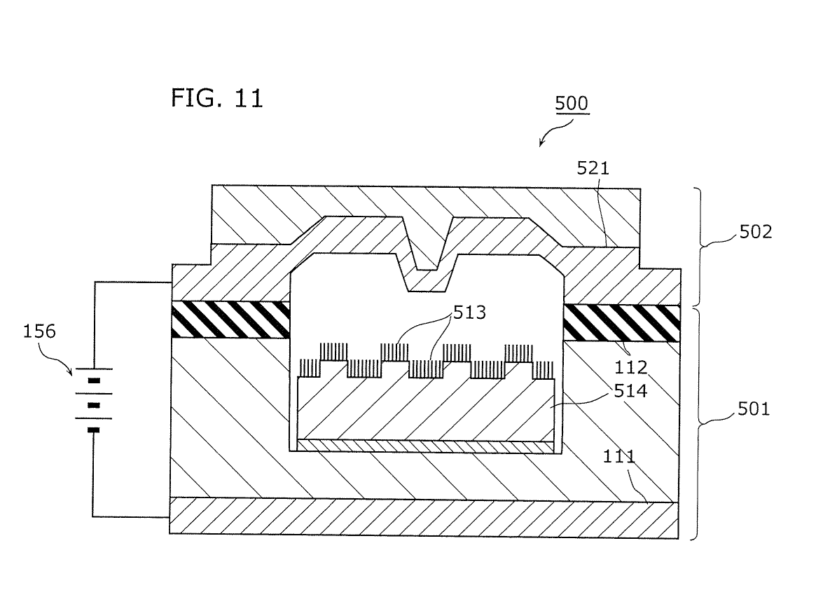

FIG. 11 is a cross-sectional view showing the fourth variant embodiment of the THz wave radiating device of the present embodiment. As shown in FIG. 11, a THz wave radiating device 500 may have a structure in which plural bundles of carbon nanotubes are formed, as a photoelectron emission layer 513, on the outer surface of a chip 514 with periodic irregularities. Here, the chip 514 may be SiC, and a cathode wafer 501 may be formed by use of either a Si wafer or a SiC wafer.

The periodic irregularities on the outer surface of the photoelectron emission layer 513 produce periodic variations in the refractive index of the photoelectron emission layer 513 and the refractive index of the outer environment (e.g., vacuum). Such a periodic variation in a refractive index is known as photonic crystal.

In other words, if properly designed, photonic crystal can absorb maximum laser power with least reflection. Furthermore, the periodic irregularities on the outer surface of the photoelectron emission layer 513 allow its area to be virtually doubled compared with the actual area. As a result, it is possible to best convert the laser light irradiated on the photoelectron emission layer into THz wave.

### Fifth Variant Embodiment

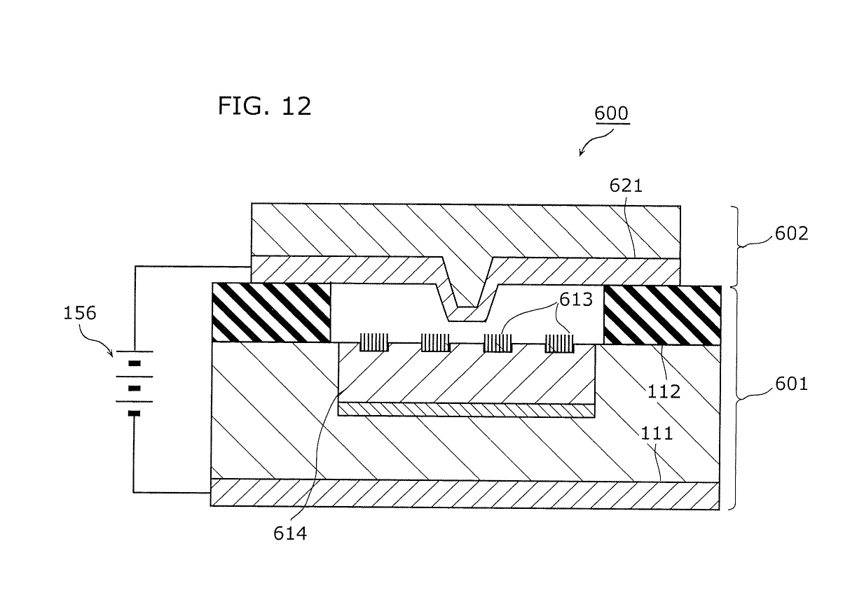

FIG. 12 is a cross-sectional view showing the fifth variant embodiment of the THz wave radiating device of the present embodiment. As shown in FIG. 12, a THz wave radiating device 600 may have a structure in which plural bundles of carbon nanotubes are periodically formed, as a photoelectron emission layer 613, on the outer surface of a chip 614. In FIG. 12, the photoelectron emission layer 613 is formed on the chip 614, which is assembled in a cathode wafer 601 as in the case of the third variant embodiment. Here, the chip 614 may be SiC, and the cathode wafer 601 may be formed by use of either a Si wafer or a SiC wafer.

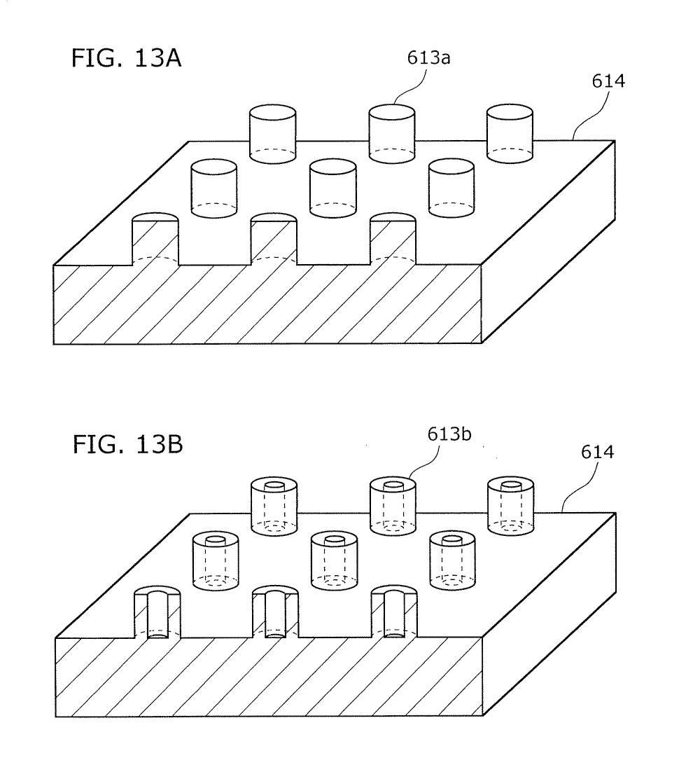

FIG. 13A is an enlarged oblique view showing the photoelectron emission layer 613 of the THz wave radiating device 600 of the fifth variant embodiment, and FIG. 13B shows its variant embodiment. Each bundle of carbon nanotubes may be formed on the chip 614 in the form of a small, columnar projection 613a as shown in FIG. 13A, or may be formed on the chip 614 in the form of a small, tubular projection 613b as shown in FIG. 13B. This structure enables photoelectrons to be emitted efficiently.

### Sixth Variant Embodiment

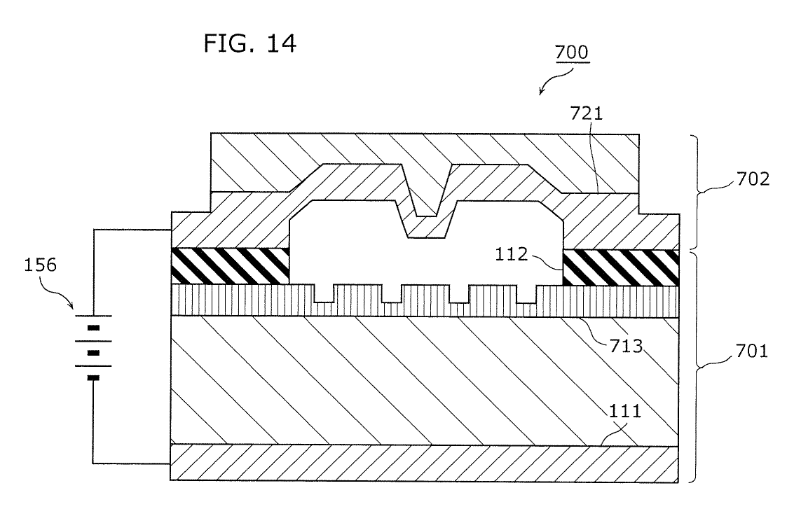

FIG. 14 is a cross-sectional view showing the sixth variant embodiment of the THz wave radiating device of the present embodiment. As shown in FIG. 14, in the fabrication of a THz wave radiating device 700, a photoelectron emission layer 713 with a periodic structure may be formed on the outer surface of a cathode wafer 701 before the formation of the electrical insulating layer 112. Here, it is assumed that the cathode wafer 701 is formed by use of a SiC wafer.

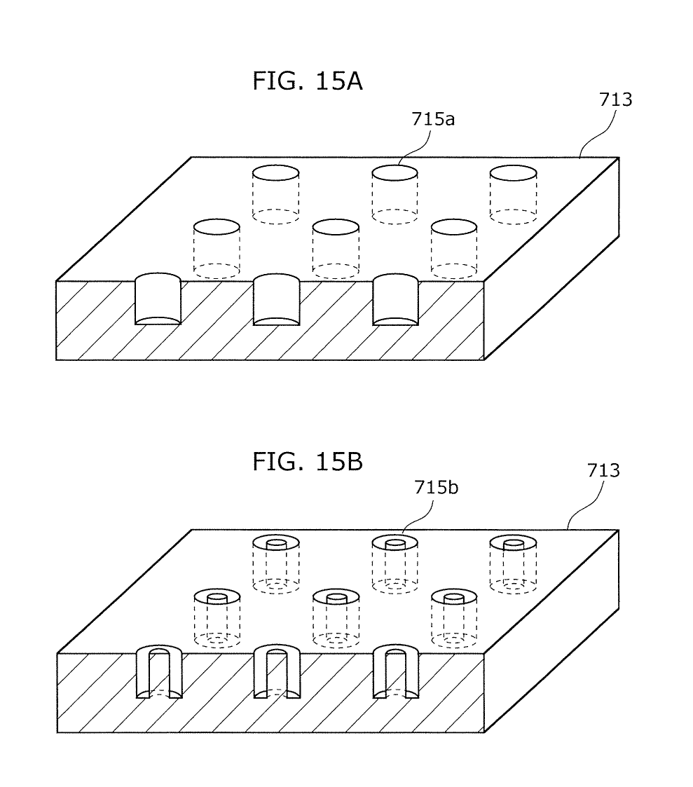

FIG. 15A is an enlarged oblique view showing the photoelectron emission layer 713 of the THz wave radiating device 700 of the sixth variant embodiment, and FIG. 15B shows its variant embodiment. Small holes 715a may be formed in the photoelectron emission layer 713 as shown in FIG. 15A, or doughnut-like holes 715b may be formed in the photoelectron emission layer 713 as shown in FIG. 15B.

### Seventh Variant Embodiment

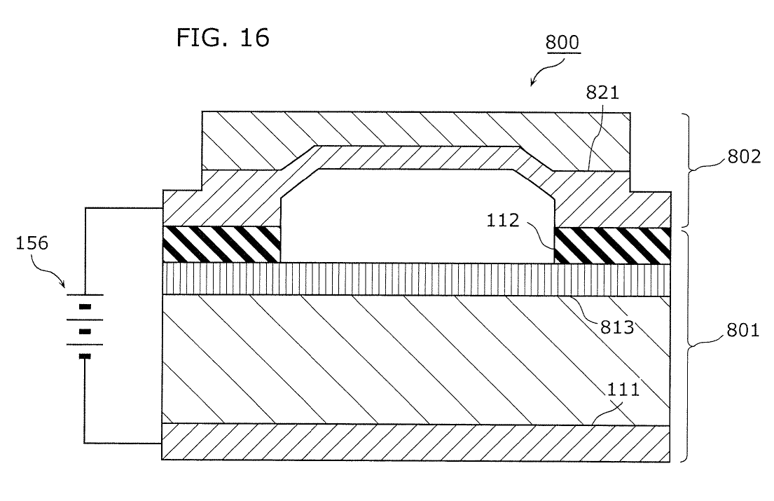

FIG. 16 is a cross-sectional view showing the seventh variant embodiment of the THz wave radiating device of the present embodiment. As shown in FIG. 16, in the fabrication of a THz wave radiating device 800, one of the cathode electrode layer 111 and an anode electrode layer 821 may be formed by means of photolithography and etching. When this is done, the cathode electrode layer 111 and the anode electrode layer 821 may be formed so that the gap between these layers is greater in the central portion than in the periphery, and the gap between these layers is uniform in the central portion whereas the gap between these layers is not uniform in the periphery. Here, it is assumed that the cathode wafer 801 is formed by use of a SiC wafer.

### Eighth Variant Embodiment

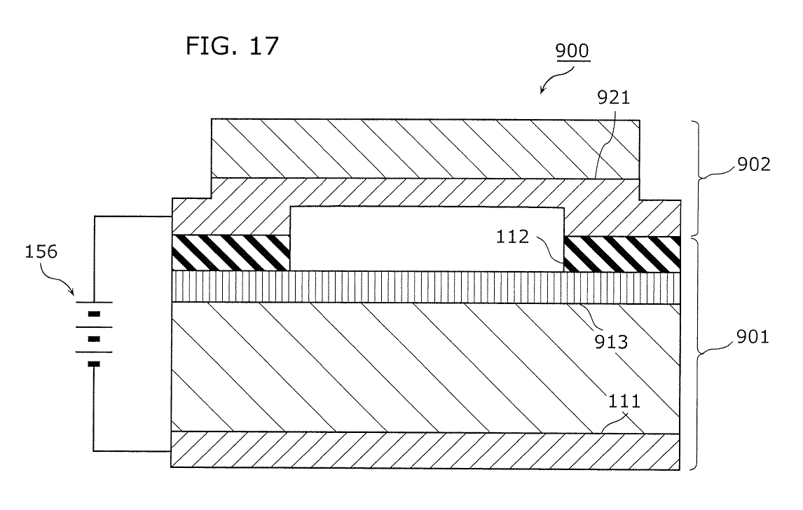

FIG. 17 is a cross-sectional view showing the eighth variant embodiment of the THz wave radiating device of the present embodiment. As shown in FIG. 17, a THz wave radiating device 900 may have a structure in which the gap between the cathode electrode layer 111 and an anode electrode layer 921 is precisely uniform. Here, it is assumed that a cathode wafer 901 is formed by use of a SiC wafer.

### Ninth Variant Embodiment

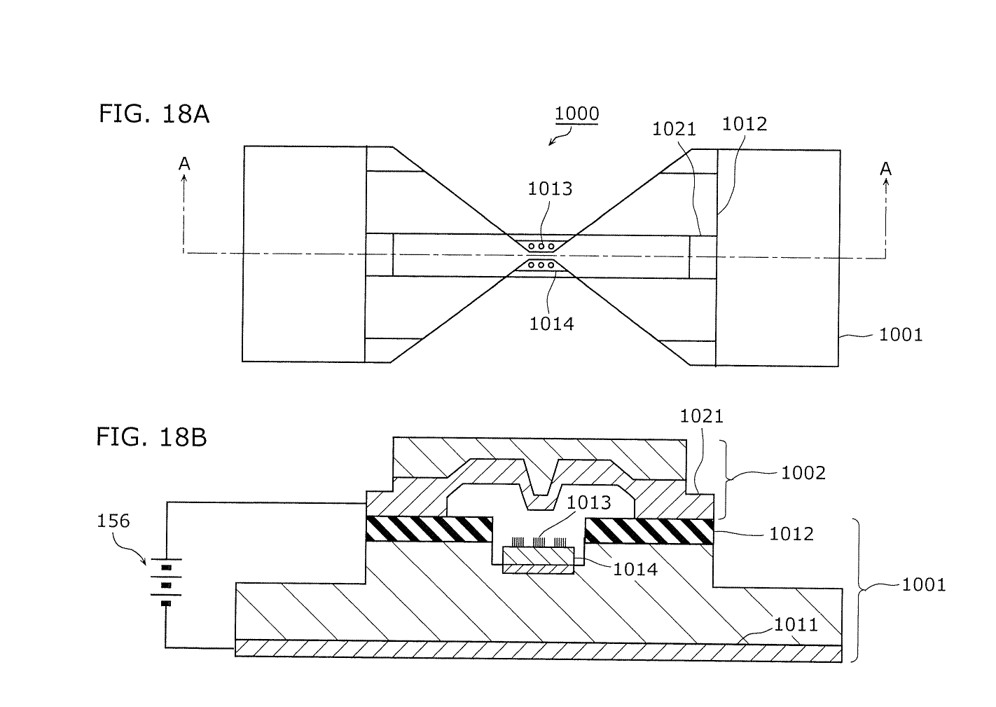

FIG. 18A is a top view showing the ninth variant embodiment of the THz wave radiating device of the present embodiment, and FIG. 18B is a cross-sectional view showing the THz wave radiating device when it is cut along the line A-A and seen in the direction indicated by the arrows. As shown in FIG. 18A, notches are formed in a THz wave radiating device 1000 in the direction in which THz wave is irradiated. This structure allows the THz wave radiating device to radiate directional THz wave. Furthermore, the center portion of the THz wave radiating device is designed so that THz wave is coupled to the waveguides.

### Tenth Variant Embodiment

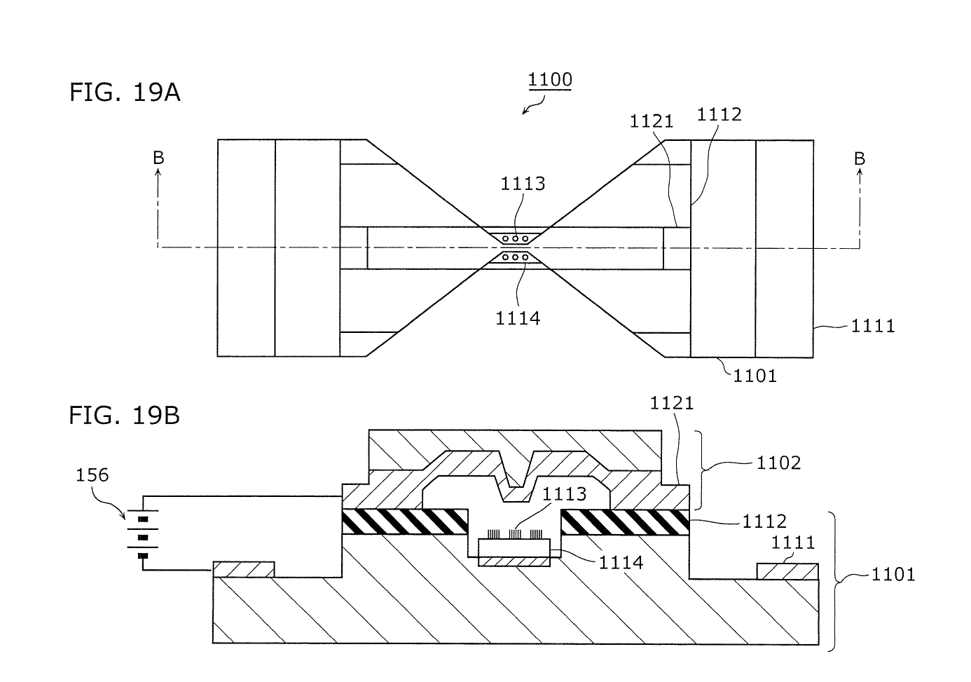

FIG. 19A is a top view showing the tenth variant embodiment of the THz wave radiating device of the present embodiment, and FIG. 19B is a cross-sectional view showing the THz wave radiating device when it is cut along the line B-B and seen in the direction indicated by the arrows. As shown in FIG. 19A, a THz wave radiating device 1100 may have a structure in which a cathode electrode layer 1111 of a cathode wafer 1101 is formed on the surface closer to the surface of an anode wafer 1102 on which an anode electrode layer 1112 is formed.

### Other Variant Embodiments

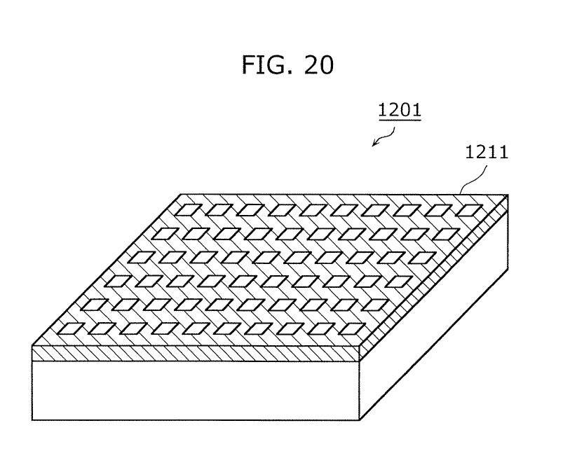

FIG. 20 is an oblique view showing a variant embodiment of any of the cathode electrode layer and the anode electrode layer in the THz wave radiating device of the present embodiment. As shown in FIG. 20, a cathode electrode layer 1211 formed in a cathode wafer 1201 may be made of one of a non-transparent material or a transparent material. A cathode electrode layer 1211 may further be formed in the form of mesh. The pitch size of such mesh is set to be in the range between 10 μm to 300 μm. The same applies to the anode electrode layer.

The cathode electrode layer/anode electrode layer with the is above structure is capable of controlling the phase of THz wave and serving as a filter.

Although only an exemplary embodiment of this invention has been described in detail above, those skilled in the art will readily appreciate that many modifications are possible in the exemplary embodiment without materially departing from the advantages of this invention. Accordingly, all such modifications are intended to be included within the scope of this invention.

### INDUSTRIAL APPLICABILITY

The present invention is applicable for use as a THz wave radiating device that radiates electromagnetic wave in the THz range, and particularly as a THz wave radiating device that provides improved efficiency of THz wave radiation.

What is claimed is:

1. A terahertz (THz) wave radiating device that radiates electromagnetic wave in a THz range, said device comprising:
a first electrode layer;
a second electrode layer which forms a pair with said first electrode layer;
an electrical insulating layer (i) which is positioned between said first electrode layer and said second electrode layer, and (ii) in which an aperture is formed and a vacuum is produced, said aperture passing through said electrical insulating layer in a direction in which said electrical insulating layer was laminated; and
a photoelectron emission layer (i) which is positioned between said electrical insulating layer and said second electrode layer, (ii) which touches said electrical insulating layer, and (iii) which emits photoelectrons to said aperture.

2. The THz wave radiating device according to claim 1, comprising:
a first wafer in which said first electrode layer is formed; and
a second wafer in which said second electrode layer and said photoelectron emission layer are formed,
wherein said electrical insulating layer is sandwiched between said first wafer and said second wafer in such a manner that a surface of said second wafer on which said photoelectron emission layer is formed is opposite to a surface of said first wafer on which said first electrode layer is formed.

3. The THz wave radiating device according to claim 2,
wherein a V groove is formed on a surface of said second wafer opposite to a surface on which said second electrode layer is formed, and said photoelectron emission layer is formed on an outer surface of said V groove.

4. The THz wave radiating device according to claim 2,
wherein two V grooves are formed on the surface of said first wafer on which said first electrode layer is formed, and said first electrode layer is formed over said two V grooves.

5. The THz wave radiating device according to claim 1,
wherein said photoelectron emission layer is λ/4n in thickness, where λ is a wavelength of incident light irradiated on said photoelectron emission layer, and n is a refractive index of said photoelectron emission layer.

6. The THz wave radiating device according to claim 1,
wherein an outer surface of said photoelectron emission layer has periodic irregularities.

7. The THz wave radiating device according to claim 1,
wherein said photoelectron emission layer is made of one of the following carbon nanostructures: carbon nanotube, carbon nanowall, and carbon nanofiber.

8. The THz wave radiating device according to claim 7,
wherein an effective length of said carbon nanotube ranges from 50 nm to 50 μm.

9. The THz wave radiating device according to claim 1,
wherein one of said first electrode layer and said second electrode layer is made of a material having transparency to incident light.

10. The THz wave radiating device according to claim 9,
wherein the material includes Indium Tin Oxide (ITO).

11. The THz wave radiating device according to claim 1,
wherein one of said first electrode layer and said second electrode layer is in a mesh form.

12. The THz wave radiating device according to claim 11,
wherein a pitch size of the mesh ranges from 10 μm to 300 μm.

13. The THz wave radiating device according to claim 2,
wherein a groove is formed on a surface of said second wafer opposite to a surface on which said second electrode layer is formed, and a chip is assembled with said groove, said chip including said photoelectron emission layer thereon.

14. The THz wave radiating device according to claim 13,
wherein a V groove is formed on a surface of said chip opposite to a surface which touches said groove formed in said second wafer, and said photoelectron emission layer is formed on an outer surface of the V groove.

15. The THz wave radiating device according to claim 1,
wherein a notch is formed in said THz wave radiating device in a direction in which the electromagnetic wave is irradiated.

16. A method for driving a terahertz (THz) wave radiating device that radiates electromagnetic wave in a THz range,
wherein the THz wave radiating device includes:
a first electrode layer;
a second electrode layer which forms a pair with the first electrode layer;
an electrical insulating layer (i) which is positioned between said first electrode layer and said second electrode layer, and (ii) in which an aperture is formed and a vacuum is produced, the aperture passing through the electrical insulating layer in a direction in which the electrical insulating layer was laminated; and
a photoelectron emission layer (i) which is positioned between the electrical insulating layer and the second electrode layer, (ii) which touches the electrical insulating layer, and (iii) which emits photoelectrons to the aperture, and
said method comprising
applying a bias voltage to the first and second electrode layers formed in the THz wave radiating device in synchronization with a pulse of incident light directed towards the THz wave radiating device.

17. The method for driving a THz wave radiating device according to claim 16,
wherein a driver which converts the incident light into pulses and a driver which converts the bias voltage to pulses are driven by the same oscillator.

18. A method for fabricating a terahertz (THz) wave radiating device that radiates electromagnetic wave in a THz range, said method comprising:
forming a first electrode layer on a first wafer, the first electrode layer having transparency to incident light;
forming a second electrode layer on a second wafer, the second electrode layer generating an electrical field in pairs with the first electrode layer;
forming a photoelectron emission layer on the second wafer, the photoelectron emission layer emitting photoelectrons; and
wafer-bonding the first wafer and the second wafer in such a manner that the photoelectron emission layer is positioned between the first electrode layer and the second electrode layer and that an electrical insulating layer is sandwiched between the first wafer and the second wafer, the electrical insulating layer having an aperture that is formed in accordance with a position of a portion of the photoelectron emission layer from which photoelectrons are emitted, and the aperture passing through the electrical insulating layer in a direction in which the electrical insulating layer was laminated.

19. The method for fabricating a THz wave radiating device according to claim 18, comprising
sealing, into a vacuum container, the THz wave radiating device that has been completed in said wafer-bonding of the first wafer and the second wafer.

20. A method for fabricating a photoelectron emission layer (i) which is included in a terahertz (THz) wave radiating device that radiates electromagnetic wave in a THz wave range, and (ii) which emits photoelectrons that produce the electromagnetic wave, said method comprising:
depositing a silicon carbide (SiC) on a carbon board by chemical vapor deposition (CVD), the carbon board having a groove therein and the SiC being deposited on a surface of the carbon board in which the groove is formed;
separating the deposited SiC on the carbon board from the carbon board after the SiC is deposited on the carbon board to a predetermined thickness;
polishing a surface of the deposited SiC separated from the carbon board, the surface having touched the carbon board; and
growing a layer of carbon nanostructure on a surface of the polished SiC opposite to the surface having been polished, by annealing the SiC at high temperature.
